(19) United States
(12) Patent Application Publication
(10) Pub. No.: US 2022/0290296 A1
(43) Pub. Date: Sep. 15, 2022

(54) METHOD FOR THE PRODUCTION OF A POLYMER COATED GRAPHENE LAYER STRUCTURE AND GRAPHENE LAYER STRUCTURE

(71) Applicant: PARAGRAF LIMITED, Somersham (GB)

(72) Inventors: Hugh GLASS, Somersham (GB); Ivor GUINEY, Somersham (GB); Martin TYLER, Somersham (GB); Robert WALLIS, Somersham (GB); Simon THOMAS, Somersham (GB)

(73) Assignee: PARAGRAF LIMITED, Somersham (GB)

(21) Appl. No.: 17/625,042

(22) PCT Filed: Jul. 7, 2020
(86) PCT No.: PCT/EP2020/069083

§ 371 Date: Jan. 5, 2022

(30) Foreign Application Priority Data
Jul. 16, 2019 (GB) 1910192.2

(51) Int. Cl. C23C 16/26; H01L 33/56; H01L 31/18; H01L 43/14; C23C 16/56

(52) U.S. Cl. CPC C23C 16/26; H01L 33/56; H01L 31/18; H01L 43/14; C23C 16/56; H01L 2933/005; B82Y 40/00

(57) ABSTRACT

The present invention provides a method for the production of a polymer-coated graphene layer structure, the method comprising: providing a substrate on a heated susceptor in a reaction chamber, the chamber having a plurality of cooled inlets arranged so that, in use, the inlets are distributed across the substrate and have a constant separation from the substrate, supplying a flow comprising a precursor compound through the inlets and into the reaction chamber to thereby decompose the precursor compound and form a graphene layer structure on the substrate, wherein the inlets are cooled to less than 100° C. and the susceptor is heated to a temperature of at least 50° C. in excess of a decomposition temperature of the precursor, wherein the graphene layer structure has a first charge carrier density, spin-coating a composition having a second charge carrier density onto the graphene layer structure to form an air-impermeable coating, wherein the coated graphene layer structure has a third charge carrier density which is less than the first charge carrier density, wherein the composition comprises a polymer or polymer precursor.

The present invention relates to a method for the production of a polymer-coated graphene layer structure. In particular, the method of the invention provides an improved approach to forming a graphene layer structure having a reduced charge carrier density through the application of a polymer-coating having a complementary charge carrier density that dopes the graphene layer structure upon which it is deposited. Moreover, the present invention relates to a graphene layer structure provided with an air-impermeable membrane coating.

Graphene is a well-known material with a plethora of proposed applications driven by the material's theoretical extraordinary properties. Good examples of such properties and applications are detailed in ‘The Rise of Graphene’ by A. K. Geim and K. S. Novoselev, Nature Materials, Volume 6, 183-191, March 2007 and in the focus issue of Nature Nanotechnology, Volume 9, Issue 10, October 2014.

WO 2017/029470, the content of which is incorporated herein by reference, discloses methods for producing two-dimensional materials. Specifically, WO 2017/029470 discloses a method of producing two-dimensional materials such as graphene, comprising heating a substrate held within a reaction chamber to a temperature that is within a decomposition range of a precursor, and that allows graphene formation from a species released from the decomposed precursor; establishing a steep temperature gradient (preferably >1000° C. per meter) that extends away from the substrate surface towards an inlet for the precursor; and introducing precursor through the relatively cool inlet and across the temperature gradient towards the substrate surface. The method of WO 2017/029470 may be performed using vapour phase epitaxy (VPE) systems and metal-organic chemical vapour deposition (MOCVD) reactors.

“Tunable transport characteristics of p-type graphene field-effect transistors by poly(ethylene imine) overlayer” by T. Feng et al., Carbon, Volume 77, 2014, 424-430 discloses a graphene field-effect transistor comprising a graphene layer having an overlayer of poly(ethylene imine) applied by spin coating.

“Controlled Ambipolar-to-Unipolar Conversion in Graphene Field-Effect Transistors Through Surface Coating with Poly(ethylene imine)/Poly(ethylene glycol) Films” by Z. Yan et al., Small, Volume 8, No. 1, 2012, 59-62 discloses a graphene field-effect transistor comprising a graphene layer coated with a film of poly(ethylene glycol) applied by spin coating.

Graphene is being investigated for a range of potential applications. Most notable is the use of graphene in electronic devices such as LEDs, photovoltaic cells, Hall sensors, diodes and the like.

However, there remains a need for a method of producing a graphene layer structure having a reduced charge carrier density. In particular, the performance of a Hall sensor can be significantly improved by having a reduced charge carrier density. That is, there remains a need for a method that overcomes the problems associated with the contamination of graphene layer structures with unavoidable impurities which result an increase in the charge carrier density of the graphene layer structure.

It is an object of the present invention to provide an improved method for producing a graphene layer structure which overcomes, or substantially reduces, problems associated with the prior art or at least provides a commercially useful alternative.

Accordingly, in a first aspect there is provided a method for the production of a polymer-coated graphene layer structure, the method comprising:
providing a substrate on a heated susceptor in a reaction chamber, the chamber having a plurality of cooled inlets arranged so that, in use, the inlets are distributed across the substrate and have a constant separation from the substrate,
supplying a flow comprising a precursor compound through the inlets and into the reaction chamber to thereby decompose the precursor compound and form a graphene layer structure on the substrate, wherein the inlets are cooled to less than 100° C. and the susceptor is heated to a temperature of at least 50° C. in excess of a decomposition temperature of the precursor, wherein the graphene layer structure has a first charge carrier density,
spin-coating a composition onto the graphene layer structure to form an air-impermeable coating,
wherein the coated graphene layer structure has a second charge carrier density which is less than the first charge carrier density,
wherein the composition comprises a polymer or polymer precursor.

The present disclosure will now be described further. In the following passages, different aspects/embodiments of the disclosure are defined in more detail. Each aspect/embodiment so defined may be combined with any other aspect/embodiment or aspects/embodiments unless clearly indicated to the contrary. In particular, any feature indicated as being preferred or advantageous may be combined with any other feature or features indicated as being preferred or advantageous.

The term graphene layer structure as used herein means one or more layers of graphene stacked to form a coating of graphene on the substrate. The graphene layer structure may comprise from 1 to 100 layers, preferably from 2 to 50, more preferably from 3 to 20 layers and most preferably from 5 to 10 layers. Preferably, the graphene comprises more than one layer of graphene, since this provides improved electrical properties to a final graphene-containing device.

MOCVD is a term used to describe a system used for a particular method for the deposition of layers on a substrate. While the acronym stands for metal-organic chemical vapour deposition, MOCVD is a term in the art and would be understood to relate to the general process and the apparatus used therefor and would not necessarily be considered to be restricted to the use of metal-organic reactants or to the production of metal-organic materials. Instead, the use of this term indicates to the person skilled in the art a general set of process and apparatus features. MOCVD is further distinct from CVD techniques by virtue of the system complexity and accuracy. While CVD techniques allow reactions to be performed with straight-forward stoichiometry and structures, MOCVD allows the production of difficult stoichiometries and structures. An MOCVD system is distinct from a CVD system by virtue of at least the gas distribution systems, heating and temperature control systems and chemical control systems. An MOCVD system typically costs at least 10 times as much as a typical CVD system. CVD techniques cannot be used to achieve high quality graphene layer structures.

MOCVD can also be readily distinguished from atomic layer deposition (ALD) techniques. ALD relies on step-wise reactions of reagents with intervening flushing steps used to remove undesirable by products and/or excess reagents. It does not rely on decomposition or dissociation of the reagent in the gaseous phase. It is particularly unsuitable for the use of reagents with low vapour pressures such as silanes, which would take undue time to remove from the reaction chamber. MOCVD growth of graphene is discussed in WO 2017/029470.

The method of WO 2017/029470 provides two-dimensional materials with a number of advantageous characteristics including: very good crystal quality; large material grain size; minimal material defects; large sheet size; and self-supporting. Graphene is a well-known term in the art and refers to an allotrope of carbon comprising a single layer of carbon atoms in a hexagonal lattice. The term graphene used herein encompasses structures comprising multiple graphene layers stacked on top of each other. The graphene layer structures disclosed herein are distinct from graphite since the layer structures retain graphene-like properties.

Generally, it is preferred to have a substrate that is as thin as possible to ensure thermal uniformity across the substrate during graphene production. The total thickness of the substrate is typically 50 to 300 μm, preferably 100 μm to 200 μm and more preferably about 150 μm. However, thicker substrates would also work and thick silicon wafers are up to 2 mm thick. The minimum thickness of the substrate is however determined in part by the substrate's mechanical properties and the maximum temperature at which the substrate is to be heated. The maximum area of the substrate is dictated by the size of the preferably close coupled reaction chamber. Preferably, the substrate has a diameter of at least 6 inches (15 cm), preferably 6 to 24 inches (15 to 61 cm) and more preferably 6 to 12 inches (15 to 30 cm). The substrate can be cut after growth to form individual devices using any known method.

Exemplary substrates that may be used in the method as described herein include silicon (Si), silicon carbide (SiC), silicon dioxide (SiO₂), sapphire (Al₂O₃) and III-V semiconductor substrates or combinations of two or more thereof. III-V semiconductor substrates may include binary III-V semiconductor substrates such as GaN and AlN and also tertiary, quaternary and higher order III-V semiconductor substrates such as InGaN, InGaAs, AlGaN, InGaAsP. Preferably, the graphene layer structure is provided on a substrate selected from silicon, silicon carbide, silicon dioxide, sapphire and III-V semiconductors. According to preferred embodiments, the substrate may be a light-emitting or light-sensitive device, such as an LED or a photovoltaic cell. A particularly preferred substrate is sapphire, since this is electrically insulative. Moreover, it has a high thermal capacity allowing the graphene to be processed with a laser to form the Hall sensor without damaging the graphene layer structure (as disclosed in GB 2570124).

Preferably, the substrate is an electronic device, even more preferably a light-emitting or light-sensitive device or a Hall sensor.

It is preferred that the substrate provides a crystalline surface upon which the graphene is produced as ordered crystal lattice sites provide a regular array of nucleation sites that promote the formation of good graphene crystal overgrowth. The most preferred substrates provide a high density of nucleation sites. The regular repeatable crystal lattice of substrates used for semiconductor deposition is ideal, the atomic stepped surface offering diffusion barriers.

The chamber has a plurality of cooled inlets arranged so that, in use, the inlets are distributed across the substrate and have a constant separation from the substrate. The flow comprising a precursor compound may be provided as a horizontal laminar flow or may be provided substantially vertically. Inlets suitable for such reactors are well known and include Planetary and Showerhead reactors available from Aixtron®.

The spacing between the substrate surface upon which the graphene is formed and the wall of the reactor directly above the substrate surface has a significant effect on the reactor thermal gradient. It is preferred that the thermal gradient is as steep as possible which correlates to a preferred spacing that is as small as possible. A smaller spacing changes the boundary layer conditions at the substrate surface that in turn promotes uniformity of graphene layer structure formation. A smaller spacing is also highly preferred as it allows refined levels of control of the process variables, for example reduced precursor consumption through lower input flux, lower reactor and hence substrate temperature which decreases stresses and non-uniformities in the substrate leading to more uniform graphene production on the substrate surface and hence, in most cases, significantly reduced process time.

Experimentation suggests a maximum spacing of about 100 mm is suitable. However, more reliable and better quality two-dimensional crystalline material is produced using a much smaller spacing equal to or less than about 20 mm, such as 1 to 5 mm; a spacing equal or less than about 10 mm promotes the formation of stronger thermal currents proximate the substrate surface that increase production efficiency.

Where a precursor is used that has a relative low decomposition temperature such that there is likely to be a more than negligible degree of decomposition of the precursor at the temperature of the precursor inlet, a spacing below 10 mm is strongly preferred to minimise the time taken for the precursor to reach the substrate.

During the production method, a flow is supplied comprising a precursor compound through the inlets and into the reaction chamber to thereby decompose the precursor compound and form graphene on the substrate. The flow comprising a precursor compound may further comprise a dilution gas. Suitable dilution gases are discussed in more detail below.

Preferably, the precursor compound is a hydrocarbon. Preferably a hydrocarbon which is a liquid at room temperature and most preferably a C₅ to C₁₀ alkane. The use of simple hydrocarbons is preferred since this gives a pure source of carbon with gaseous hydrogen as a by-product. In addition, since the hydrocarbons are liquid at room temperature, they can be obtained in a highly pure liquid form at low cost.

The precursor is preferably in the gas phase when passed over the heated substrate. There are two variables to be considered: pressure within the preferably close coupled reaction chamber and the gas flow rate into the chamber.

The preferred pressure selected depends upon the precursor chosen. In general terms, where precursors of greater molecular complexity are used, improved two-dimensional crystalline material quality and rate of production is observed using lower pressures, e.g. less than 500 mbar. Theoretically, the lower the pressure the better, but the benefit provided by very low pressures (e.g. less than 200 mbar) will be offset by very slow graphene formation rates.

Conversely, for less complex molecular precursors, higher pressures are preferred. For example, where methane is used as a precursor for graphene production, a pressure of 600 mbar or greater may be suitable. Typically, it is not expected to use pressures greater than atmospheric because of its detrimental impact on substrate surface kinetics and the mechanical stresses placed on the system. A suitable pressure can be selected for any precursor through simple empirical experimentation, which may involve for example, five test runs using respective pressures of 50 mbar, 950 mbar and three others of equidistance intervals between the first two. Further runs to narrow the most suitable range can then be conducted at pressures within the interval identified in the first runs as being most suitable.

The precursor flow rate can be used to control the graphene deposition rate. The flow rate chosen will depend upon the amount of the species within the precursor and the area of the layer to be produced. Precursor gas flow rate needs to be high enough to allow coherent graphene layer structure formation on the substrate surface. If the flow is above an upper threshold rate, bulk material formation, e.g. graphite, will generally result or increased gas phase reactions will occur resulting in solid particulates suspended in the gas phase that are detrimental to graphene formation and/or may contaminate the graphene layer structure. The minimum threshold flow rate can be theoretically calculated using techniques known to the person skilled in the art, by assessing the amount of the species required to be supplied to the substrate to ensure sufficient atomic concentrations are available at the substrate surface for a layer to form. Between the minimum and upper threshold rates, for a given pressure and temperature, flow rate and graphene layer structure growth rate are linearly related.

Preferably, a mixture of the precursor with a dilution gas is passed over the heated substrate within a preferably close coupled reaction chamber. The use of a dilution gas allows further refinement of the control of the carbon supply rate.

It is preferred that the dilution gas includes one or more of hydrogen, nitrogen, argon and helium. These gases are selected because they will not readily react with a large number of available precursors under typical reactor conditions, nor be included in the graphene layer structure. Notwithstanding, hydrogen may react with certain precursors. Additionally, nitrogen can be incorporated into the graphene layer structure under certain conditions. In such instances, one of the other dilution gases can be used.

In spite of these potential problems, hydrogen and nitrogen are particularly preferred because they are standard gases used in MOCVD and VPE systems.

The susceptor is heated to a temperature of at least 50° C. in excess of a decomposition temperature of the precursor, more preferably from 100 to 200° C. in excess. The preferred temperature to which the substrate is heated is dependent upon the precursor selected. The temperature selected needs to be high enough to allow at least partial decomposition of the precursor in order to release the species, but preferably not so high as to promote increased recombination rates in the gas phase away from the substrate surface and hence production of unwanted by-products. The selected temperature is higher than the complete decomposition temperature to promote improved substrate surface kinetics and so encourage formation of graphene with good crystal quality.

In order for there to be a thermal gradient between the substrate surface and the introduction point for precursor, the inlet will need to be of a lower temperature than the substrate. For a fixed separation, a greater temperature difference will provide a steeper temperature gradient. As such it is preferred that at least the wall of the chamber through which the precursor is introduced, and more preferably the walls of the chamber are cooled. Cooling may be achieved using a cooling system, for example, using fluid, preferably liquid, most preferably water, cooling. The reactor's walls may be maintained at constant temperature by water cooling. The cooling fluid may flow around the inlet(s) to ensure that the temperature of the inner surface of the reactor wall through which the inlets extend, and thus of the precursor itself as it passes through the inlet and into the reaction chamber, is substantially lower than the substrate temperature. The inlets are cooled to less than 100° C., preferably 50 to 60° C.

A close coupled reaction chamber provides a separation between the substrate surface upon which the graphene is formed and the entry point at which the precursor enters the close coupled reaction chamber that is sufficiently small that the fraction of precursor that reacts in the gas phase within the close coupled reaction chamber is low enough to allow the formation of graphene. The upper limit of the separation may vary depending upon the precursor chosen, substrate temperate and pressure within the close coupled reaction chamber.

Compared with the chamber of a standard CVD system, the use of a close coupled reaction chamber, which provides the aforementioned separation distance, allows a high degree of control over the supply of the precursor to the substrate; the small distance provided between the substrate surface on which the graphene is formed and the inlet through which the precursor enters the close coupled reaction chamber, allows for a steep thermal gradient thereby providing a high degree of control over the decomposition of the precursor.

The relatively small separation between the substrate surface and the chamber wall provided by a close coupled reaction chamber, compared with the relatively large separation provided by a standard CVD system allows:

1) a steep thermal gradient between the precursor's entry point and the substrate surface;

2) a short flow path between the precursor entry point and the substrate surface; and

3) a close proximity of the precursor entry point and the point of graphene formation.

These benefits enhance the effects that deposition parameters including substrate surface temperature, chamber pressure and precursor flux have on the degree of control over the delivery rate of the precursor to the substrate surface and the flow dynamics across the substrate surface.

These benefits and the greater control provided by these benefits enable minimisation of gas phase reactions within the chamber, which are detrimental graphene deposition; allow a high degree of flexibility in the precursor decomposition rate, enabling efficient delivery of the species to the substrate surface; and gives control over the atomic configuration at the substrate surface which is impossible with standard CVD techniques.

Through both simultaneously heating the substrate and providing cooling to the wall of the reactor directly opposite the substrate surface at the inlet, a steep thermal gradient can be formed whereby the temperature is a maximum at the substrate surface and drops rapidly towards the inlet. This ensures the reactor volume above the substrate surface has a significantly lower temperature than the substrate surface itself, largely reducing the probability of precursor reaction, in the gas phase, until the precursor is proximate the substrate surface.

An alternative design of MOCVD reactor is also contemplated which has been demonstrated to be efficient for graphene growth as described herein. This alternative design is a so-called High Rotation Rate (HRR) or “Vortex” flow system. Whereas the close coupled reactor described above focused on creating graphene using a very high thermal gradient, the new reactor has a significantly wider spacing between the injection point and growth surface or substrate. Close coupling allowed extremely rapid dissociation of precursors delivering elemental carbon, and potentially other doping elements, to the substrate surface allowing the formation of graphene layer structures. In contrast, the new design relies on a vortex of the precursors.

In the new reactor design, in order to promote laminar flow over the surface this system utilizes a higher rotation rate to impinge a high level of centrifugal acceleration on the injected gas stream. This results in a vortex type fluid flow within the chamber. The effect of this flow pattern is a significantly higher residency time of the precursor molecules proximate to the growth/substrate surface compared to other reactor types. For the deposition of graphene this increased time is what promotes the formation of elemental layers.

However, this type of reactor does have a couple of parasitic issues, firstly the amount of precursor required to achieve the same amount of growth as other reactors increases due to the reduced mean free path that this flow regime causes, resulting in more collisions of precursor molecules delivering non-graphene growth atomic recombination. However, the use of reagents which are relatively cheap means that this problem can be readily overcome. Additionally, the centrifugal motion has varying impacts on atoms and molecules of different sizes resulting in the ejection of different elements at different velocities. While this probably assists graphene growth due to the uniform rate of carbon supply with ejection of unwanted precursor by-products it can be detrimental to desired effects such as elemental doping. It is therefore preferred to use this design of reactor for undoped graphene, such as is desirably used for hall sensors or filters.

Examples of such a reaction system is the Veeco Instruments Inc. Turbodisc® technology, K465i® or Propel® tools.

Preferably, the reactor used herein is a high rotation rate reactor. This alternative design of reactor may be characterised by its increased spacing and high rotation rate. Preferred spacings are from 50 to 120 mm, more preferably 70 to 100 mm. The rotation rate is preferably from 100 rpm to 3000 rpm (1.67 Hz to 50 Hz), preferably 1000 rpm to 1500 rpm (16.7 Hz to 25 Hz).

The graphene layer structure formed on the substrate has a first charge carrier density. A charge carrier density is an intrinsic property of the graphene formed. In practice, graphene is n-doped due to the interaction with the substrate on which it forms having an intrinsic charge carrier density of typically greater than 1×10¹² cm⁻², such as 2×10¹² cm⁻².

Charge carrier density (also known as charge carrier concentration) refers to the number of charge carriers, typically, per unit volume. However, with two-dimensional materials such as graphene, the value is given per unit area (i.e. typically in cm⁻²). The charge carrier density of graphene layer structure may be measured by any technique known in the art. Charge carriers densities as described herein are those measured under standard conditions at 0 V at room temperature.

Accordingly, whilst the composition itself will have a charge carrier density, the composition is likely to be electrically insulative by itself. That is, a composition (comprising, preferably consisting of, a polymer and/or polymer precursor and/or solvent and/or dopant) is formed of components that have a large energy gap (i.e. band gap or HOMO/LUMO energy gap). An insulator may have a gap of about 5 eV or greater and anything above about 6 eV and especially 8 eV or even 10 eV is particularly insulating. Such materials have negligible charge carrier density.

The skilled person would readily appreciate that the charge carrier density of the composition would not be an essential feature in doping the graphene layer structure and modification of the first charge carrier density to the second charge carrier density. Instead, the composition comprises a component with a HOMO or LUMO of an energy sufficient to allow addition or removal of charge carriers (electrons or holes) from the graphene layer structure. For example, a p-type dopant provides a LUMO of an energy similar to that of the filled band of the graphene layer structure in order to facilitate removal of the electron from the graphene band structure (thus creating a charge-carrying hole). Conversely, an n-type dopant provides a HOMO of energy similar to that of an unfilled band of the graphene layer structure thereby allowing donation of the electron to the graphene band structure.

The concentration of components in the composition may be controlled by diluting the composition with a solvent before spin-coating the composition onto the graphene layer structure. Whilst the composition may already comprise a solvent, the composition may be further diluted by the addition of further solvent, be it the same solvent or an alternative. In one preferred embodiment, the composition is diluted by the addition of water. The concentration of the components in the composition may be used to control the extent of doping of the graphene layer structure to achieve a desired second charge carrier density.

The method comprises spin-coating a composition onto the graphene layer structure to form an air-impermeable coating. Spin-coating is used to deposit thin films onto substantially flat surfaces such as the surface of a graphene layer structure. A small amount of the material is applied to the center of the substrate whilst the substrate is not spinning or spinning slowly. The substrate is then spun at high speed in order to spread the coating material by centrifugal force. Typically, rotation speeds may be greater than 1000 rpm (16.7 Hz), however, good film quality may be achieved at speeds as low at 500 rpm (8.3 Hz). Rotation speeds may be up to 12000 rpm (200 Hz). Rotation is typically continued until the film is fully dry; therefore, rotation time typically depends on the boiling point and vapour pressure of the solvent. Common solvents include water as well as hydrocarbons, halocarbons, ethers, esters, alcohols, amines and amides such as isopropyl alcohol, acetone, toluene, anisole, N-methyl-2-pyrrolidone and chloroform, including combinations thereof. Rotation is continued until a desired thickness of film is achieved; this may be approximately 30 seconds. Preferably, the thickness of the air-impermeable coating according to the present invention is less than 10 μm, more preferably less than 1 μm and most preferably less than 100 nm. There is no particular lower limit for the thickness, provided that a conformal film can be formed across the surface. Preferred thicknesses include from 1 to 75 nm, preferably 5 to 50 nm and most preferably from 10 to 20 nm. Preferably, the polymer coating has a substantially uniform thickness across the surface of the graphene layer structure.

The composition as described herein comprises a polymer or a polymer precursor. Compositions may include, for example, poly(methyl methacrylate) (PMMA), polyethylene terephthalate (PET), polyphenylene ether ether sulfone (PPEES), poly(2,6-dimethyl-1,4-phenylene oxide), polyurethane, polyethylene, polyvinylidene fluoride (PVDF) and/or poly(tetrafluoroethylene) (PTFE). In a preferred embodiment of the present invention, the composition comprises a carboxylate-containing polymer and/or poly(2,6-dimethyl-1,4-phenylene oxide) (PPO). In a particularly preferred embodiment, the polymer coating comprises PMMA, PPEES and/or PPO. The method of forming a polymer coating may comprise spin-coating a solution comprising the polymeric material. Alternatively, the method may comprise spin-coating a polymer precursor which may then be subsequently polymerised to form the air-impermeable polymer coating. By way of example, the method of forming a polymer coating comprising PMMA may comprise spin-coating which comprises spin-coating a precursor comprising methyl methacrylate on a surface of a graphene layer structure. After spinning, a post-bake (annealing) step is performed to polymerise the methyl methacrylate and form the PMMA polymeric coating. A post-bake (annealing) step may comprise heating at about 100° C. to about 200° C. for about 1 minute to about 120 minutes. This may be carried out on a hot-plate (such as for small sized substrates) or in an oven. Preferably, PMMA may be coated by spin-coating a solution of PMMA, such as a toluene solution of PMMA, over the graphene layer structure to form an air-impermeable PMMA coating.

In a particularly preferred embodiment, the polymer coating comprises PPEES and/or PPO. Accordingly, the composition preferably comprises PPEES and/or PPO. A polymer coating comprising PPEES and/or PPO is particularly advantageous as a result of having a higher glass transition temperature than other polymer coatings (such as PMMA). The glass transition temperature (Tg) of PMMA is about 130° C. whilst the Tg of PPEES and PPO is about 192° C. and about 211° C., respectively. Such polymer coating allow for the polymer-coated graphene layer structure to be used for high temperature applications without the coating causing additional doping of the graphene layer structure which may otherwise lead to a drift in the electronic properties of the graphene through continued use (at high temperatures). Accordingly, air-impermeable coating preferably comprises a polymer that has a Tg of greater than 150° C., preferably greater than 175° C. and even more preferably greater than 190° C. A solvent comprising N-methyl-2-pyrrolidone (NMP) is a suitable solvent for dissolving PPEES and/or PPO for forming a composition for use as described herein. When PPMA is used, it is particularly preferred for the solvent to comprise anisole.

Preferably, the composition comprises a polymer precursor and the method further comprises treating the spin-coated composition to form the air-impermeable coating. Preferably, the step of treating the spin-coated composition to form the air-impermeable coating comprises heating and/or UV-exposing the spin-coated composition. In another embodiment, the polymer precursor forms a carboxylate-containing polymer, preferably PMMA. Alternatively, the polymer precursor preferably forms a polymer coating comprising PPEES and/or PPO as described herein.

The inventors have found that graphene, in particular the surface of graphene, is sensitive to a range of gases present in ambient air. The properties of graphene (such as electrical and optical properties) can be dramatically altered by the adsorption of atmospheric gases, in particular oxygen and water. The extent to which the adsorption of atmospheric gases have an effect on the properties of graphene layer structure may depend on factors such as the magnitude of doping. When exposed to air, graphene undergoes a reaction, which results in higher carrier concentrations and reduced mobility.

Accordingly, the method as described herein preferably further comprises not exposing the graphene layer structure to an oxygen-containing atmosphere before the air-impermeable coating has been formed. Therefore, a graphene layer structure having a low carrier concentration may be achieved. The step of not exposing the graphene layer structure to an oxygen-containing atmosphere preferably comprises maintaining the graphene layer structure under an inert atmosphere. However, the step of not exposing the graphene layer structure to an oxygen-containing atmosphere may comprise minimising the exposure, such as less than 1 minute, less than 20 seconds or less than 10 seconds. This may be preferable so as to enable a simpler manufacturing process without having to ensure such a strict exclusion of contact with the atmosphere without substantially affecting the graphene properties due to the minimal exposure.

It is particularly preferred that where the method comprises not exposing the graphene layer structure to an oxygen-containing atmosphere, the method comprises providing a graphene layer structure on the substrate by VPE or MOCVD as described herein. Such a method allows for the direct formation of a graphene layer structure on a surface of a substrate within a reaction chamber without the need for further processing to provide graphene on a desirable substrate (i.e. one for use in electronic devices) for subsequent coating.

In contrast, graphene transfer processes which are known in the prior art, for example, may require etching of the metal substrate upon which graphene has been formed. Typical substrates include copper. The etching and transfer processes can have a detrimental effect on the quality of the graphene layer structure, the etching solution results in chemical modification of the surface of the graphene layer structure and such processes also take place in the presence of water and/or air. The copper itself results in uncontrolled doping of the graphene layer structure, which then creates significant difficulties for subsequent processing to form devices from such graphene having specific charge carrier densities. This is particularly true for the preparation of multiple graphene products on a commercial scale since the charge carrier density of every graphene sheet need be determined and the amount the subsequent processing adapted accordingly. However, the extent to which the subsequent process conditions would need be adapted in such a scenario may not be obvious. Therefore, in targeting a specific value for a product produced on a commercial scale (i.e. during the production of a plurality of polymer-coated graphene layer structures and subsequent devices), transfer processes are less suitable.

A VPE or MOCVD reactor may itself be provided in an inert atmosphere (such as a glovebox) so as to enable the relevant steps of the method to be carried out under an atmosphere that is substantially free of air and moisture (in other words, one that has less than about 1000 ppm O₂ and less than about 1000 ppm H₂O, preferably less than about 500 ppm of each of O₂ and H₂O, even more preferably less than about 100 ppm).

In a preferred embodiment of the present invention, the method further comprises removing graphene from the substrate before the spin-coating step to provide a graphene layer structure having upper and lower exposed surfaces. Further, the spin-coating step involves coating both the upper and lower exposed surfaces to form the air-impermeable coating, preferably, wherein the graphene layer structure is fully encapsulated by the air-impermeable coating. Full encapsulation protects the graphene layer structure from the atmospheric gases which may otherwise have a detrimental effect on the graphene layer structure properties.

It is even more preferable that the coated graphene layer structure is removed from the substrate to provide a lower exposed surface and spin-coated with a carboxylate-containing polymer onto the lower exposed surface to form a second air-impermeable coating.

The composition preferably comprises a doping agent (also known as a dopant), more preferably a p-type dopant. Examples of p-type dopants include 7,7,8,8-tetracyanoquinodimethane (TCNQ), 2,3,5,6-tetrafluoro-7,7,8,8-tetracyanoquinodimethane (F₄TCNQ), phenyl-C61-butyric acid methyl ester (PCBM), bis(ethylenedithio)tetrathiafulvalene (BEDT-TTF) and NDI(CN)₄ (tetracyano-napthalenediimide). In a particularly preferred embodiment, the polymer coating is doped with F₄TCNQ; the composition therefore preferably comprises F₄TCNQ.

The effect on the first charge carrier density in the graphene may also be controlled by diluting the composition with deionised water before spin-coating the composition onto the graphene layer structure.

The concentration of components in the composition may be selected to as to counteract the intrinsic doping of the graphene, thereby reducing the number of charge carriers in the coated graphene layer structure relative to the freshly prepared and exposed graphene layer structure. In accordance with the method as described herein, the coated graphene layer structure has a second charge carrier density that is less than the first charge carrier density. In a preferred embodiment, the second charge carrier density is less than 5×10¹¹ cm⁻², more preferably less than 4×10¹¹ cm⁻², more preferably less than 2×10¹¹ cm⁻², and most preferably less than 5×10¹⁰ cm⁻². The coated graphene layer structure formed by the method as described herein advantageously has a lower carrier concentration than the initial graphene layer structure along with increased charge carrier mobilities.

In a preferred embodiment of the present invention, the graphene layer structure is processed to form a Hall sensor before or after the step of spin-coating. A Hall sensor (Hall effect sensor) is a well-known component in the art. It is a transducer that varies its output voltage in response to a magnetic field. Hall sensors are used for proximity switching, positioning, speed detection, and current sensing applications. In a Hall sensor, a thin strip of a conductor has a current applied along it. In the presence of a magnetic field, the electrons are deflected towards one edge of the conductor strip, producing a voltage gradient across the short-side of the strip (perpendicular to the feed current). In contrast to inductive sensors, Hall sensors have the advantage that they can detect static (non-changing) magnetic fields.

Accordingly, a preferred embodiment provides a method for the production of a Hall sensor, the method comprising:
providing a substrate on a heated susceptor in a reaction chamber, the chamber having a plurality of cooled inlets arranged so that, in use, the inlets are distributed across the substrate and have a constant separation from the substrate,
supplying a flow comprising a precursor compound through the inlets and into the reaction chamber to thereby decompose the precursor compound and form a graphene layer structure comprising two or more sublayers of graphene on the substrate, preferably from 2 to 50 layers of graphene, wherein the inlets are cooled to less than 100° C. and the susceptor is heated to a temperature of at least 50° C. in excess of a decomposition temperature of the precursor, wherein the graphene layer structure has a first charge carrier density,
spin-coating a composition onto the graphene layer structure to form an air-impermeable coating,
wherein the coated graphene layer structure has a second charge carrier density which is less than the first charge carrier density and less than 1×10¹² cm⁻²,
wherein the composition comprises a polymer or polymer precursor, and
wherein the graphene layer structure is processed to form a Hall sensor before or after the step of spin-coating. Preferably, the substrate is sapphire or another electrically insulative material.

The inventors have found that the Hall sensor provided with multiple layers of graphene, and coated in this way, provides a particularly efficient and sensitive sensor for this purpose. Surprisingly, the effect of the specific polymer coating was able to reduce effect of the charge carriers throughout the graphene layers of the graphene layer structure.

In a further aspect of the present invention, there is provided a graphene layer structure provided with an air-impermeable coating having a charge carrier density of less than 1×10¹² cm⁻², preferably less than 5×10¹¹ cm⁻², such as less than 1×10¹¹ cm⁻², 5×10¹⁰ cm⁻² or even more preferably less than 1×10¹⁰ cm⁻². The polymer-coated graphene layer structure as described herein may be obtainable by, and preferably is obtained by, the method described herein. Accordingly, there is provided a polymer-coated graphene layer structure obtainable by the method described herein. Moreover, there is also provided a device comprising the polymer-coated graphene layer structure as described herein.

In a further aspect there is provided a method for the production of a plurality of polymer-coated graphene layer structures, each having a target charge carrier density, the method comprising:
(a) providing a graphene layer structure on a substrate, the graphene layer structure having a first charge carrier density;
(b) determining the first charge carrier density of the graphene layer structure;
(c) spin-coating a composition onto the graphene layer structure to form an air-impermeable coating, wherein the components and their concentrations in the composition are selected so as to provide a polymer-coated graphene layer structure having a second charge carrier density, wherein the second charge carrier density is within 10% of the targeted charge carrier density; and
(d) repeating steps (a) and (c) to provide a plurality of polymer-coated graphene layer structures on a plurality of corresponding substrates without determining the charge carrier density of each graphene layer structure.

Accordingly, the method provides for the production of one or more polymer-coated graphene layer structures wherein the charge carrier density of each product is preselected (or predetermined) prior to carrying out the steps of manufacture. Moreover, the method comprises repeating steps (a) and (c) to provide a plurality of polymer-coated graphene layer structures, thereby omitting the step of determining the charge carrier density of the further graphene layer structure(s) provided on a substrate(s) in subsequent cycles.

In achieving the target charge carrier density, the final polymer-coated graphene layer structure product (that is any of the plurality of products) will have a (second) charge carrier density that is within 10% (numerically) of the target value, preferably within 5% of the target value, and even more preferably within 3%.

The method is particularly suitable wherein in the step of providing a graphene layer structure on a substrate having a first charge carrier density comprises providing the graphene layer structure by the method described herein with reference to WO 2017/029470 (and may also be generally referred to as MOCVD). The inventors have found that by providing a graphene layer structure by MOCVD (using the method as described herein and/or in accordance with WO 2017/029470), the charge carrier density of the graphene layer structure on a substrate may be known without having to experimentally determine the value. The method allows for extremely high consistency from one sample of graphene to the next, which allows for the large scale and commercial production of graphene for use in electronic devices. The method of producing a plurality of polymer-coated graphene layer structures comprises a single step of determining the first charge carrier density of a first graphene layer structure on substrate. Thus, when a further graphene layer structure is provided by the same method, the first charge carrier density need not be experimentally determined in order to allow the formation of a polymer-coated graphene layer structure having any target charge carrier density (preferably the same as that of the first coated product).

The method is simpler since it does not require a step of experimentally determining the charge carrier density. Instead, the person skilled in the art may simply determine the charge carrier density of a graphene layer structure produced in a first test experiment. They may then reliably continue to repeat the experiment using the same conditions to provide graphene layer structures that have substantially the same charge carrier density in accordance with the method. Other prior art methods for providing graphene layer structures on a substrate are less reliable, with certain methods being substantially less reliable, at being able to provide graphene with consistent properties, such as charge carrier density, from one sample to the next. Therefore, by using certain prior art methods of providing graphene, the charge carrier density would have to be determined for each sample of graphene prior to the spin-coating step in order to ensure the specific target charge carrier density is achieved.

Charge carrier densities that are substantially the same (or even said to be the same) may be said to be within 10% of one another, preferably within 5%, and even more preferably within 3%. By way of example only, a first polymer-coated graphene layer structure having a second charge carrier density of 4×10¹¹ cm⁻² may be substantially the same as that of another product (such as one produced without having to experimentally determine the first charge carrier density of the uncoated graphene layer structure) of 3.6×10¹¹ cm⁻² (10%) or 4.2×10¹¹ cm⁻² (5%).

Whilst the intrinsic (first) charge carrier density of a graphene layer structure provided on a substrate may vary depending on the substrate, the instruments and the methods used in its synthesis, graphene layer structures produced by the same instruments and methods on the same substrates may have substantially similar or identical charge carrier densities. Accordingly, the skilled person may know the charge carrier density of a manufactured graphene layer structure without having to undertake the step of experimentally determining the first charge carrier density, nevertheless, this may be easily done so using techniques known in the art.

With the aim of producing a polymer-coated graphene layer structure having a target charge carrier density, the method then requires spin-coating a composition onto the graphene layer structure to form an air-impermeable coating as discussed herein.

Knowing the first charge carrier density of the graphene layer structure, the components of the composition, and their concentrations, are selected so as to provide a polymer-coated graphene layer structure having the target charge carrier density. Preferably, the concentration of components in the composition is selected by dilution of the composition with a solvent before spin-coating in order to control the extent of doping in the graphene layer structure so as to achieve the target charge carrier concentration.

According to yet a further aspect there is provided a method for the production of a polymer-coated graphene layer structure having a charge carrier density of 1×10¹³ cm⁻² to 8×10¹³ cm⁻², the method comprising:
(a) providing a graphene layer structure on a substrate, the graphene layer structure having a first charge carrier density;
(b) determining the first charge carrier density of the graphene layer structure;
(c) spin-coating a composition onto the graphene layer structure to form an air-impermeable coating, wherein the composition is selected to increase the first charge carrier density of the graphene layer structure and provide the polymer-coated graphene layer structure having a charge carrier density of 1×10¹³ cm⁻² to 8×10¹³ cm⁻².

Therefore, this aspect of the invention relates to the formation of a polymer-coated graphene layer structure that has a charge carrier density greater than that of the graphene layer structure before having the coating applied. A graphene layer structure will have a first charge carrier density that is dependent on the method by which it is produced and it not particularly limited in any aspect of the invention described herein. Typically, a graphene layer structure may have a first charge carrier density of from 1×10¹¹ cm⁻² to 1×10¹³ cm⁻² or from 1×10¹² cm⁻² to 1×10¹³ cm⁻².

The composition may be the same as that described herein with regards to the other aspects of the invention, i.e. it may be preferable that the composition comprises a doping agent that is a p-type dopant. This is particularly preferable if the graphene layer structure provided on the substrate having a first charge carrier density is intrinsically p-type doped. It is preferable that the doping agent is an n-type dopant. Again, this is particularly preferable where the graphene layer structure provided on the substrate having a first charge carrier density is intrinsically n-type doped. A doping agent of the same type and the intrinsic graphene doping facilitates higher levels of charge carrier densities in the final graphene layer structure. Polyethylene imine is a preferable example of an n-type dopant.

Whilst amount of the doping agent in the composition is not particularly limited, the composition as described herein may comprise from 1 ppm to 100000 ppm doping agent by weight of the composition, preferably 5 ppm to 50000 ppm, even more preferably from 10 ppm to 10000 ppm.

In a preferred embodiment of the present invention, the amount of p-type doping agent is orders of magnitude higher than that which might have otherwise been required in order to reduce the charge carrier density of the graphene (i.e. to reduce the number of free electrons in the intrinsically n-type doped graphene layer structure) without having introduced an excessive number of holes which would result in an increase in charge carrier density.

In this preferred embodiment, the overdoping of the graphene layer structure with a composition comprising at least 5 wt % doping agent, preferably at least 10 wt % doping agent, allows for subsequent high temperature processing whilst still achieving a second charge carrier density that is less than the first charge carrier density. Preferably, the method further comprises annealing which may occur at temperatures greater than 150° C., such as greater than 200° C. At these temperatures, the inventors have observed an increase in the n-type doping of graphene on substrates, which has hitherto precluded the use of such high temperature processing methodologies.

One preferred high temperature process includes solder sealing. A polymer-coated graphene layer structure having been coated with a composition having a high level of doping agent may be solder sealed by lining the edge of a hermetic package with solder, such as SAC305 solder, and heating to greater than 200° C., for example 230° C., to form a metal seal with the material in the package. The use of a high level of doping agent in the composition allows for the counteraction of the intrinsic increase in n-type doping which would otherwise occur. In other words, a particularly high p-type doped polymer-coated graphene layer structure is provided and subsequently heat-treated to thereby induce further n-type doping (and ultimately obtain a product having a second charge carrier density that is less than the first charge carrier density). As discussed above, this method is particularly preferred for high temperature applications and therefore preferably is carried out using PPEES and/or PPO polymer coatings. Accordingly, the inventors have been able to provide a device hermetically sealed in a package, the polymer-coated graphene layer structure of the device having a (second) charge carrier density of less than 6×10¹¹ cm⁻².

### FIGURES

The present invention will now be described further with reference to the following non-limiting FIGURES, in which:

FIG. 1 shows a cross-section of the layers of a coated graphene structure as described herein.

FIG. 1 shows a cross-section of an exemplary graphene structure (101) comprising a graphene layer structure (103) and an air-impermeable coating (104) that is a polymer coating. The graphene layer structure (103) is provided on the surface of a substrate (102).

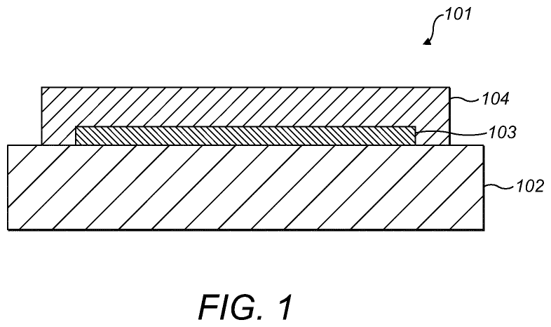

### EXAMPLES

### Example 1

PPEES is dissolved in NMP by heating a mixture at 50° C. on a hotplate for 7 hours followed by gentle agitation with a glass rod and then filtering so as to achieve a concentration of 3 wt %. To the composition is then added 2,3,5,6-tetrafluoro-7,7,8,8-tertacyanoquinodimethane (F₄TCNQ) at concentrations of either 0.1 mg/mL or 1 mg/mL. The composition was then spun onto a graphene layer structure on a sapphire substrate at 1000 rpm (16.7 Hz) for 180 s followed by an annealing step at 130° C. for 5 minutes to dry the film.

Conductive Ag paint is used to contact the underlying graphene by heating at 200° C. for 30 minutes on a hotplate, thereby softening the PPEES and allowing the paint to dissolve through and form the silver contact on the graphene.

### Example 2

Poly(2,6-dimethyl-1,4-phenylene oxide) (PPO) is dissolved in anisole by heating a mixture at 50° C. on a hotplate for 7 hours followed by gentle agitation with a glass rod and then filtering so as to achieve a concentration of 3.4 wt %. To the composition is then added 2,3,5,6-tetrafluoro-7,7,8,8-tertacyanoquinodimethane (F₄TCNQ) at concentrations of either 0.1 mg/mL or 1 mg/mL. The composition was spun onto a graphene layer structure on a sapphire substrate at 6000 rpm (100 Hz) for 60 s followed by annealing at 140° C. for 60 minutes to dry the film.

Next, a laser is used to ablate the polymer to expose the underlying graphene for the deposition of contacts. This is followed by electron beam deposition of Ti/Au electrode stacks on the exposed graphene.

All percentages herein are by weight unless otherwise stated or indicated by the context.

As used herein, the singular form of “a”, “an” and “the” include plural references unless the context clearly dictates otherwise. The use of the term “comprising” intended to be interpreted as including such features but not (necessarily) limited to is also intended to include the option of the features necessarily being limited to those described. In other words, the term also include the limitations of “consisting essentially of” (intended to mean that specific further components can be present provided they do not materially affect the essential characteristic of the described feature) and “consisting of” (intended to mean that no other feature may be included such that if the components were expressed as percentages by their proportions, these would add up to 100%, whilst accounting for any unavoidable impurities), unless the context clearly dictates otherwise.

The foregoing detailed description has been provided by way of explanation and illustration, and is not intended to limit the scope of the appended claims. Many variations in the presently preferred embodiments illustrated herein will be apparent to one of ordinary skill in the art, and remain within the scope of the appended claims and their equivalents.

1. A method for the production of a polymer-coated graphene layer structure, the method comprising:
providing a substrate on a heated susceptor in a reaction chamber, the chamber having a plurality of cooled inlets arranged so that, in use, the inlets are distributed across the substrate and have a constant separation from the substrate,
supplying a flow comprising a precursor compound through the inlets and into the reaction chamber to thereby decompose the precursor compound and form a graphene layer structure on the substrate, wherein the inlets are cooled to less than 100° C. and the susceptor is heated to a temperature of at least 50° C. in excess of a decomposition temperature of the precursor, wherein the graphene layer structure has a first charge carrier density,
spin-coating a composition onto the graphene layer structure to form an air-impermeable coating,
wherein the coated graphene layer structure has a second charge carrier density which is less than the first charge carrier density,
wherein the composition comprises a polymer or polymer precursor.

2. The method according to claim 1, wherein the second charge carrier density is less than 5×10¹² cm⁻².

3. The method according to claim 1, wherein the graphene layer structure is not exposed to an oxygen-containing atmosphere before the air-impermeable coating has been formed.

4. The method according to claim 1 wherein the concentration of components in the composition is controlled by diluting the composition with deionised water before coating.

5. The method according to claim 1, wherein the air-impermeable coating has a thickness of from 1 nm to 10 μm.

6. The method according to claim 1, wherein the composition comprises a carboxylate-containing polymer.

7. The method according to claim 1, wherein the composition comprises a polymer precursor and wherein the method further comprises treating the spin-coated composition to form the air-impermeable coating.

8. The method according to claim 7, wherein the step of treating the spin-coated composition to form the air-impermeable coating comprises heating and/or UV-exposing the spin-coated composition.

9. The method according to claim 7, wherein the polymer precursor forms a carboxylate-containing polymer.

10. The method according to claim 1, wherein the graphene layer structure is removed from the substrate before the spin-coating step to provide a graphene layer structure having upper and lower exposed surfaces and wherein the spin-coating step involves coating both the upper and lower exposed surfaces to form the air-impermeable coating.

11. The method according to claim 1, wherein the coated graphene layer structure is removed from the substrate to provide a lower exposed surface and wherein the method further comprises spin-coating a carboxylate-containing polymer onto the lower exposed surface to form a second air-impermeable coating.

12. The method according to claim 1, wherein the substrate is an electronic device selected from a light-emitting or light-sensitive device.

13. The method according to claim 1, wherein the graphene layer structure is processed to form a Hall sensor before the step of spin-coating.

14. A graphene layer structure provided with an air-impermeable coating, and having a charge carrier density of less than 1×10¹² cm⁻².

15. A method for the production of a plurality of polymer-coated graphene layer structures, each having a target charge carrier density, the method comprising:
(a) providing a graphene layer structure on a first substrate, the graphene layer structure having a first charge carrier density;
(b) determining the first charge carrier density of the graphene layer structure;
(c) spin-coating a composition onto the graphene layer structure to form an air-impermeable coating, wherein the components and their concentrations in the composition are selected so as to provide a polymer-coated graphene layer structure having a second charge carrier density, wherein the second charge carrier density is within 10% of the targeted charge carrier density; and
(d) repeating steps (a) and (c) to provide a plurality of polymer-coated graphene layer structures on a plurality of corresponding substrates without determining the charge carrier density of each graphene layer structure.

16. The method according to claim 15, wherein in step (a), the graphene layer structure is provided by MOCVD.

17. The method according to claim 15, wherein the concentration of components in the composition is selected by dilution of the composition with a solvent before spin-coating.

18. A method for the production of a polymer-coated graphene layer structure having a charge carrier density of 1×10¹³ cm⁻² to 8×10¹³ cm⁻², the method comprising:
(a) providing a graphene layer structure on a substrate, the graphene layer structure having a first charge carrier density;
(b) determining the first charge carrier density of the graphene layer structure;
(c) spin-coating a composition onto the graphene layer structure to form an air-impermeable coating, wherein the composition is selected to increase the first charge carrier density of the graphene layer structure and provide the polymer-coated graphene layer structure having a charge carrier density of 1×10¹³ cm⁻² to 8×10¹³ cm⁻².
